(19) United States
(12) Patent Application Publication
(10) Pub. No.: US 2026/0181846 A1
(43) Pub. Date: Jun. 25, 2026

(54) HOUSING FOR ELECTRONIC COMPONENTS WITH EMC SHIELDING

(71) Applicant: AUMOVIO Germany GmbH, Frankfurt am Main (DE)

(72) Inventors: Ralf Scheib, Wald-Michelbach (DE); Christian Bitsch, Heppenheim (DE); Lothar Springer, Oberzent (DE)

(73) Assignee: AUMOVIO Germany GmbH, Frankfurt am Main (DE)

(21) Appl. No.: 19/414,705

(22) Filed: Dec. 10, 2025

(30) Foreign Application Priority Data
Dec. 19, 2024 (DE) 102024138856.0

(51) Int. Cl. H05K 9/00; B60R 16/023; H05K 5/03; H05K 5/04

(52) U.S. Cl. CPC H05K 9/0035; B60R 16/0239; H05K 5/03; H05K 5/04; H05K 9/0026; H05K 9/0049

(57) ABSTRACT

A housing for electronic components and to a brake device having such a housing. The housing is characterized here by a high level of electromagnetic compatibility. The housing includes a cover and a base, wherein the cover and the base form a cavity for receiving and holding at least one electronic component, preferably a circuit board, including: a housing part as part of a wall of the housing, and an electronic component, which is held within the cavity. The housing part includes at least one first contact surface. The electronic component includes a second contact surface with electrical contacts. In the mounted position, the first contact surface and the second contact surface are arranged in a mutually corresponding or opposite manner, and the air gap between the first contact surface and the second contact surface is preferably 2 mm or less.

### CROSS REFERENCE TO RELATED APPLICATIONS

This application claims priority to German Application No. 102024138856.0, filed Dec. 19, 2024, the contents of such application being incorporated by reference herein.

### FIELD OF THE INVENTION

The present invention relates in general to a housing for electronic components and to a brake device having such a housing. The housing is characterized here by a high level of electromagnetic compatibility.

### BACKGROUND OF THE INVENTION

Electronic components, in particular circuit boards populated with electrical or electronic components, are received in a variety of ways in corresponding housings for protection.

Thus, in today's brake control systems, for example, electronic components of this type are correspondingly housed or held in a surrounding housing due to the ambient conditions prevailing at the mounting site. For reasons of stability, these are often formed from metal or a metallic material.

To improve the electromagnetic compatibility, appropriate electrical contacting of the metal housing, for example of a metal cover of the housing, to the circuit board can be provided. To this end, a contact spring can be provided in some housings, which contact spring can be arranged, for instance, on a cover and can be connected to a contact surface on the electronic component.

In this way, the electromagnetic compatibility can be established. However, such embodiments are costly and, depending on the design, require additional working steps in the manufacturing process, such as for example the welding of a metal strip to the housing cover. There is also the fact that, depending on the design, such a spring must be positioned very precisely. A further challenge may arise if, for example, the contact resistance is to be ensured over the entire service life of the component.

### SUMMARY OF THE INVENTION

Solutions for protecting electronic components which do not exhibit, or at least mitigate, the above-mentioned disadvantages are therefore desirable. An aspect of the invention is to provide the greatest possible electromagnetic compatibility.

An aspect of the invention is achieved in a surprisingly simple manner by a housing, in particular a two- or multi-part housing having a cover and a base, according to any one of the independent claims. Preferred embodiments and refinements of the invention can be found in the respective dependent claims.

Thus, in a first aspect, the invention relates to a housing, wherein the housing is preferably of two-part or multi-part design. According to one preferred embodiment of the invention, the housing may comprise at least two housing parts, in particular a cover and a base. The housing parts may generally comprise parts of the wall of the housing. Here, the cover and/or the base can form a cavity which serves for receiving and holding at least one electronic component, in particular at least one circuit board. The electronic component can be held in the mounted position in the cavity, for which purpose suitable holding means or receptacles may be provided.

The housing according to an aspect of the invention may be characterized in that
a housing part comprises at least one first contact surface,
wherein the electronic component comprises a second contact surface with an electrical contacting means,
wherein, in the mounted position, the first contact surface and the second contact surface are arranged in a mutually corresponding or opposite manner, and
wherein the air gap between the first contact surface and the second contact surface is preferably 2 mm or less than 2 mm.

It is particularly preferably possible for an electrical contact to be provided and configured in the mounted position between the first contact surface and the second contact surface. In the mounted position, this means that the electronic component, in particular the electronic circuit board, is held in the cavity of the housing, wherein the at least two housing parts, for example the cover and the base, are interconnected.

Within the context of an aspect of the invention, the housing, at least the housing part with the first contact surface, can be produced from an electrically conductive metallic material or can comprise an electrically conductive, metallic material, for example aluminum or an Al alloy. According to a particularly preferred embodiment of the invention, this housing part relates to the cover by means of which the housing can be closed after mounting of the electronic component has been completed. In this way, a housing which is particularly easy to assemble can be provided.

In the context of an aspect of the invention, electrical contacting can be established between the electronic component and a housing part of the housing, preferably between the circuit board and the cover. It is possible here to dispense with the use of additional components for the contacting, such as for example a contact spring, with the result that the housing for electronic components can be produced in a cost-effective manner. The assembly can also be simplified.

One advantage of an aspect of the present invention accordingly consists in the omission of the contact spring and, secondly, in the simplification of the manufacturing and assembly process, whereby costs can be reduced. In various manufacturing methods for producing a housing cover from metal, for instance for control units for brake devices (“ECU”), the deep-drawing method may already be a part in the production process, with the result that no additional process steps are required and therefore hardly any additional costs arise.

According to one preferred embodiment of the invention, the first contact surface and the second contact surface can be formed by planar surfaces or can each comprise a planar surface. This allows the first contact surface and the second contact surface to be arranged parallel or at least substantially parallel to one another.

“Substantially” means, in the context of an aspect of the invention, in relation to a variable that a deviation of up to 10%, preferably of up to 5% and particularly preferably of up to 1% may be possible between this reference variable and a possible actual value.

In the case of a circuit board as an electronic component, this can be implemented particularly simply, since a circuit board typically has a flat, planar extent, and the second contact surface can then comprise a planar region of that surface of the circuit board which points toward the first contact surface. If, for example, the first contact surface is then assigned to a cover, the second contact surface can particularly advantageously comprise a part or section of that surface of the circuit board which points toward the cover.

According to an aspect of the invention, silver or gold pads, which are often used on a circuit board to contact a contact spring, can particularly advantageously be dispensed with on the circuit board. For an aspect of the invention, it is possible to use simple contact pads, for example tin-plated contact pads, for the second contact surface instead of significantly more expensive silver or even gold pads. The second contact surface can accordingly comprise silver- and gold-free contact pads or be formed free from silver and gold components.

Configuring the contact surfaces as a planar surface furthermore offers the advantage that even a slight lateral offset of the two contact surfaces relative to one another is possible after assembly, provided that the remaining overlap is large enough. Such an offset may result for example from form and positional tolerances during manufacture and assembly, or these may be defined correspondingly more broadly. This also allows the production to be simplified, and moreover the joining of base, circuit board and cover is possible in just one mounting direction.

According to one preferred embodiment of the invention, the first contact surface may in this case comprise a projection or a bulge which is formed inward in the direction of the cavity. Said bulge may for example be realized in a particularly inexpensive manner as a deep drawing. The deep drawing may be formed with different outer contours, for example a circular outer contour, which is considered to be advantageous for reasons of production technology.

In order to allow permanent or long-term stable electrical contacting, it may also be expedient if the first and the second contact surface comprise at least one overlap region which has a predetermined minimum surface area. In the context of an aspect of the invention, the minimum surface area accordingly means that surface area for which the first and the second contact surface are arranged in a mutually corresponding or overlapping manner after assembly has been completed. This can be the region in which the air gap existing between the contact surfaces is at its smallest. This likewise assists a certain tolerance in the case of form or positional deviations of the components.

According to one advantageous embodiment of the invention, the housing and the electronic component are arranged in relation to one another in such a way that after assembly has been completed, there is only the smallest possible air gap between the two contact surfaces. Therefore, provision can be made for an air gap which is 2 mm or less to be formed between the first contact surface and the second contact surface. A small air gap is advantageous for the electrical contacting of the electronic component.

One embodiment of the invention can provide that an electrically conductive material is arranged between the first contact surface and the second contact surface, which electrically conductive material bridges and/or closes the air gap. In this way, an air gap that exists after assembly between the first and the second contact surface can be bridged in an electrically conductive manner. In the context of an aspect of the invention, an electrically conductive material is considered to be a material the electrical conductivity of which at 25° C. is greater or better than 1*10⁴ S/m, preferably greater or better than 1*10⁵ S/m, particularly preferably greater or better than 1*10⁶ S/m. The electrically conductive material can serve for electrical torsion and tolerance compensation of the individual components.

According to one preferred embodiment of the invention, the electrically conductive material may comprise an electrically conductive paste, for example an electrically conductive adhesive. The electrically conductive paste can be applied to the first contact surface and/or the second contact surface before the housing is assembled and can be cured after the assembly has been completed.

According to a further, likewise preferred embodiment of the invention, the electrically conductive material can comprise an electrically conductive sheet-like structure, for example an electrically conductive film or an electrically conductive strip.

By compressing the film, the resistance can be reduced yet further, which is considered to be advantageous for an aspect of the invention. Preferably, the air gap is formed in such a way that it is smaller than the thickness of the electrically conductive film. However, it should be noted here that excessive compression of the electrically conductive sheet-like structure, in particular of an electrically conductive film, may be unfavorable, since said compression can lead to deformation of the circuit board. However, such deformations or transverse forces acting on the circuit board can lead to damage to the circuit board or to components applied thereon.

According to one development of an aspect of the invention, the first contact surface and the second contact surface can also be in direct contact with one another or touch one another. This can be achieved for example by a small interference fit, wherein a flexibility or yielding of the circuit board or of the housing part, for example of the cover, can be utilized. In this case, a corresponding pretreatment of the respective surfaces of the contact surfaces may also be provided in order to improve the conductivity.

In a further refinement of an aspect of the invention, provision may also be made for the first and the second contact surface to comprise functional elements corresponding to one another for form-fitting joining of the components. Such functional elements can comprise, for example, snap-action hooks or press-in contacts or press-in pins which engage into corresponding receptacles and in this way create a detachable or non-detachable connection.

In order to ensure the desired electrical contacting, at least some of the corresponding surfaces of the functional elements can be produced from an electrically conductive material or can comprise such an electrically conductive material. This can be, for example, a coating made of an electrically conductive material. According to one embodiment of the invention, the electronic component, in particular the circuit board, can be equipped with at least one contact pin formed in this way, which can then, during the course of assembly, engage into a corresponding receptacle in the housing part, in particular in the cover.

In a further aspect of the invention, the invention also comprises a brake device, in particular for a motor vehicle, which comprises at least one control unit, for example a brake control unit (ECU), wherein the control unit can comprise a housing as described above.

An aspect of the invention is therefore also suitable wherever electrical connections between different components are realized by using spring contacts.

Further details of aspects of the invention will emerge from the description of the illustrated exemplary embodiments and from the appended claims.

### BRIEF DESCRIPTION OF THE DRAWINGS

In the drawings:

FIG. 1 shows a plan view and two side views of a circuit board according to an aspect of the invention with a contact surface,

FIG. 2 shows a partial oblique view of a circuit board having a functional element, and

FIG. 3 shows a further plan view and a side view of a detail of a housing according to an aspect of the invention.

### DETAILED DESCRIPTION OF EXEMPLARY EMBODIMENTS

In the following detailed description of preferred embodiments, identical reference numerals for the sake of clarity denote substantially identical parts in or on these embodiments. To better illustrate the invention, the preferred embodiments illustrated in the figures are however not always drawn to scale. For the sake of clarity, only those elements that are relevant for the design of the solution according to the invention are presented.

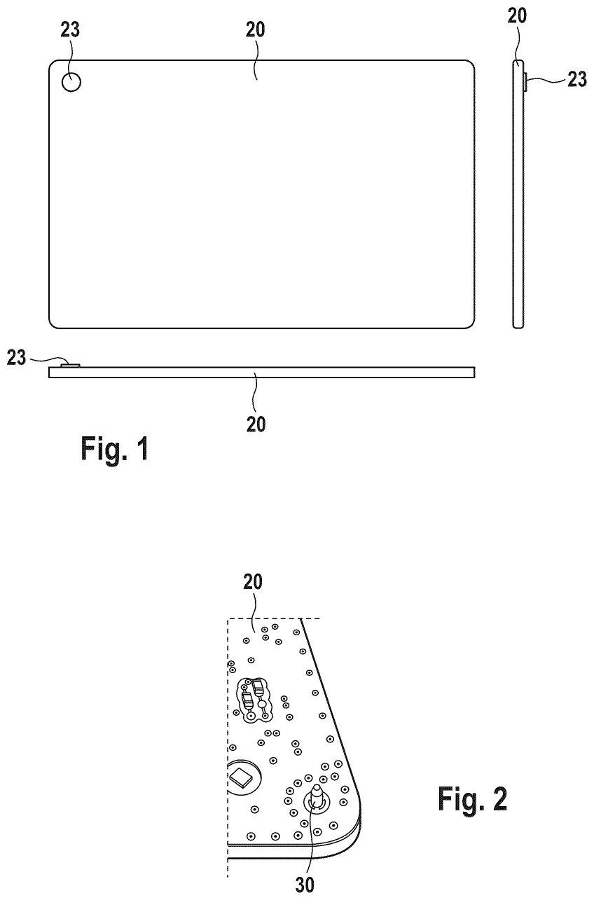

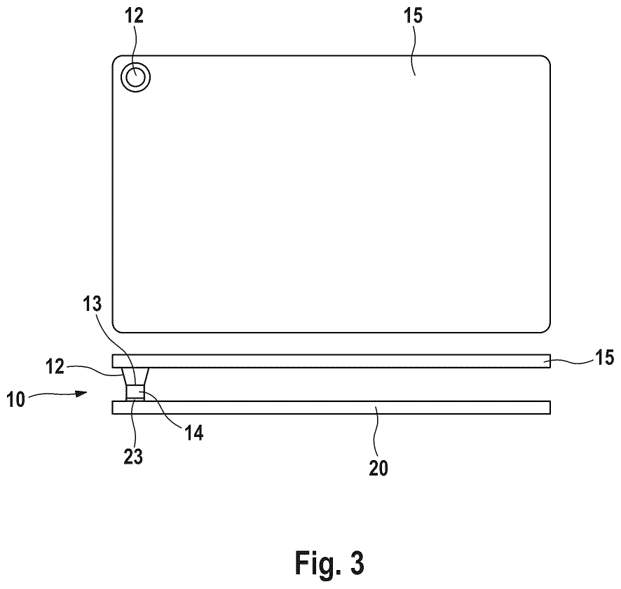

FIG. 1 shows a plan view and two side views of a circuit board 20 according to the invention with a contact surface according to an embodiment of the invention, FIG. 2 shows a detailed oblique view of a further circuit board 20 with a functional element, and FIG. 3 shows a further plan view and a side view of a detail of a housing 10 according to the invention having a circuit board 20 and a cover 15.

A first aspect of the invention relates to a housing 10, wherein the housing 10 is of multi-part design. In the embodiment of the invention shown in a detail in FIG. 3, the housing 10 comprises a cover 15 in addition to a base.

The cover 15 and the base form a cavity for receiving and holding at least one electronic component 20, which in the present example comprises a circuit board. In the mounted position, the electronic component 20, in particular the circuit board, is received and held in the cavity, for which purpose suitable holding means or receptacles may be provided (not shown).

The housing 10 according to an aspect of the invention thus comprises
a housing part as part of a wall of the housing 10, and
an electronic component 20 which is held in the cavity,
wherein the housing part comprises at least one first contact surface 13,
wherein the electronic component 20 comprises a second contact surface 23 with an electrical contacting means,
wherein, in the mounted position, the first contact surface 13 and the second contact surface 23 are arranged in a mutually corresponding or opposite manner, and
wherein the air gap between the first contact surface 13 and the second contact surface 23 is preferably 2 mm or less than 2 mm.

In the discussed exemplary embodiments, the housing part having the first contact surface 13 comprises the cover 15, which is considered to be favorable. Fundamentally however, other housing parts, for example sidewalls, can comprise a corresponding first contact surface 13 with the same functions as described below.

As soon as the cover 15 has been connected to the base as intended and/or the housing 10 is closed by means of the cover 15, an electrical contacting between the electronic component 20, in particular the circuit board, and the cover 15 can be produced. In this case, the cover is produced entirely or at least in the region of the first contact surface 13 from an electrically conductive material. In the exemplary embodiment of FIG. 2, the cover 15 is produced entirely from an electrically conductive material, e.g. aluminum or an Al alloy. In this way, electrical contacting between the circuit board and the cover 15 can be provided.

One significant advantage of an aspect of the present invention consists in the significantly simplified construction in comparison with an embodiment from the prior art in which an additional contact spring is used in the cover. Simple assembly in a preferential direction is also possible.

According to one preferred embodiment of the invention, the first contact surface 13 and the second contact surface 23 can be formed by planar surfaces or can each comprise a planar surface. In the mounted position, these two contact surfaces 13, 23 can then be arranged parallel or substantially parallel to one another, as can be seen in FIG. 3.

As shown in FIG. 1, the first contact surface 13 is formed as a projection 12 which projects inwardly in the direction of the cavity. This projection in the exemplary embodiment is realized as a deep drawing, which permits particularly cost-effective production since a cover 15 of this type is commonly formed from a thin metal sheet in a deep-drawing process and can thus be easily integrated into the production process. The deep drawing can be formed with different outer contours, for example with a circular outer contour as shown in FIG. 3. This also makes it possible to make the deep drawing correspondingly long, such that, after assembly, the two contact surfaces 13, 23 are arranged with the smallest possible spacing to one another.

The housing 10 and the electronic component 20 are arranged with respect to one another in such a way that after mounting has been completed, there is only the smallest possible air gap between the two contact surfaces 13, 23. Thus, provision is made for an air gap to be formed between the first contact surface 13 and the second contact surface 23, which air gap is 2 mm or less than 2 mm, more preferably 1 mm or less than 1 mm and particularly preferably 0.5 mm or less or 0.1 mm or less. A small air gap is advantageous for the electrical contacting of the electronic component.

It is provided according to an aspect of the invention that the first and the second contact surface 13, 23 form a corresponding region or overlap region. This overlap thus defines a minimum surface over which electrical energy can be transmitted. A larger minimum area improves the electrical contact and thus the electromagnetic compatibility of the housing 10. In general, said minimum surface area, after deduction of possible deviations in shape and position, should be at least 1 mm², preferably at least 2 mm² and particularly preferably at least 4 mm² or even more. The required minimum area is also determined here by the size of the air gap between the contact surfaces 13, 23.

One preferred embodiment of the invention can provide that an electrically conductive material 14 is arranged between the first contact surface and the second contact surface, which closes the air gap and connects the two contact surfaces 13, 23 to one another in an electrically conductive manner. In this way, an air gap that exists after assembly between the first and the second contact surface can be bridged in an electrically conductive manner.

In the context of an aspect of the invention, an electrically conductive material 14 is considered to be a material the electrical conductivity of which at 25° C. is greater or better than 1*10⁴ S/m, preferably greater or better than 1*10⁵ S/m, particularly preferably greater or better than 1*10⁶ S/m.

According to an embodiment of the invention, the electrically conductive material may comprise an electrically conductive paste, or also an electrically conductive adhesive. The electrically conductive paste can be applied to the first contact surface 13 and/or the second contact surface 23 before the housing 10 is assembled and can be cured after the assembly has been completed. Unlike a solid material, an electrically conductive paste offers greater flexibility and can thus help to compensate for minor deviations in shape or position.

According to a preferred embodiment of the invention, the electrically conductive material 14 can comprise an electrically conductive sheet-like structure, for example an electrically conductive film or an electrically conductive strip. An electrically conductive film suitable according to an aspect of the invention is available for example from the manufacturer 3M under the name “3M™ Electrically Conductive Cushion Gasket Tape ECG7033H. ECG7053H. ECG7073H”. With a minimum area of about 3 mm×3 mm, a resistance of about 1 ohm could be ascertained, which is considered sufficient for an aspect of the invention.

By slightly compressing the electrical conductive film, the resistance can be reduced yet further, which is also considered to be advantageous for an aspect of the invention. However, it must be ensured here that excessive stresses which could lead to damage are not introduced into the components involved as a result of the compression.

Such electrically conductive films are available for example in a thickness of 0.3 mm, 0.5 mm or 0.7 mm, and so the air gap between the contact surfaces can be correspondingly closed. Other films are also available in greater thicknesses, for example 1 mm or even 1.5 mm.

According to one refinement of an aspect of the invention, it is also possible for two or more thin, electrically conductive films to be arranged one above the other such that a larger air gap can be bridged. In this way, greater manufacturing tolerances can be made possible.

Preferably, the air gap is formed in these cases in such a way that it is slightly smaller than the thickness of the electrically conductive film. In the case of a film of, for example, a thickness of 0.7 mm, the air gap can be between 0.4 and 0.6 mm, and so a desired low compression can be established during mounting. In the embodiment shown in FIG. 3, a small portion of such an electrically conductive film having a thickness of 0.7 mm is arranged in an air gap of 0.6 mm between the two contact surfaces 13, 23.

According to one development of an aspect of the invention, the first contact surface 13 and the second contact surface 23 can also be in direct contact with one another or touch one another. This can be achieved for example by a small interference fit, wherein a flexibility or yielding of the circuit board or of the housing part, for example of the cover 15, can be utilized.

In a further refinement of an aspect of the invention, provision may also be made for the first and the second contact surface 13, 23 to comprise functional elements 30 corresponding to one another for form-fitting joining such components. In this regard, FIG. 2 shows, purely for illustrative purposes, an electronic component 20 in the form of a circuit board which is formed with a press-in contact or press-in pin as a functional element. Said press-in contact then, in the mounted position, engages into a corresponding receptacle in the cover 15, whereby a fixed, detachable or non-detachable connection is created.

In order to ensure electrical contacting, a part of the surface of the corresponding functional element 15, that is to say, for example, the outer surface of the press-in contact and associated section of the receptacle, is produced from or comprises an electrically conductive material. This can also be, for example, a coating made of an electrically conductive material.

A housing 10 for receiving and protecting electronic components can be made available in this way, which housing is distinguished by a high level of electromagnetic compatibility.

Said housing 10 can be used, for example, for a brake device for a motor vehicle, for instance in order to accommodate an electronic control system, and in which particularly stringent requirements are placed on the electromagnetic compatibility.

List of reference numerals:

| | |
|---|---|
| 10 | housing |
| 12 | projection |
| 13 | contact surface |
| 14 | electrically conductive material |
| 15 | cover |
| 20 | electronic component |
| 23 | contact surface |
| 30 | functional element |

1. A housing, in particular a two- or multi-part housing, having at least one cover and one base, wherein the cover and the base form a cavity for receiving and holding at least one electronic component, preferably a circuit board, comprising
a housing part as part of a wall of the housing, and
an electronic component, which is held within the cavity,
wherein the housing part comprises at least one first contact surface,
wherein the electronic component comprises a second contact surface with an electrical contacting means,
wherein, in the mounted position, the first contact surface and the second contact surface are arranged in a mutually corresponding or opposite manner, and
wherein the air gap between the first contact surface and the second contact surface is preferably 2 mm or less.

2. The housing according to claim 1, wherein in the mounted position, electrical contacting is formed between the first contact surface and the second contact surface.

3. The housing according to claim 1, wherein the housing part is manufactured with the first contact surface from an electrically conductive, metallic material or comprises an electrically conductive, metallic material, wherein the housing part preferably comprises the cover.

4. The housing according to claim 1, wherein the first contact surface and/or the second contact surface are formed as planar surfaces, wherein the first contact surface and the second contact surface are arranged parallel or at least substantially parallel to one another.

5. The housing according to claim 1, wherein the first contact surface comprises a projection, preferably a deep drawing, wherein the projection is preferably formed inwardly in the direction of the cavity.

6. The housing according to claim 1, wherein the second contact surface comprises a part of that surface of the circuit board which points toward the cover.

7. The housing according claim 1, wherein the minimum surface area in the overlap region between the first contact surface and the second contact surface is at least 1 mm², preferably at least 2 mm² and particularly preferably at least 4 mm² or even more.

8. The housing according to claim 1, wherein the air gap is less than 1 mm, preferably less than 0.5 mm, less than 0.1 mm, less than 0.01 mm.

9. The housing according to claim 1, wherein an electrically conductive material is arranged between the first contact surface and the second contact surface, which material closes the air gap.

10. The housing according to claim 1, wherein the electrically conductive material comprises an electrically conductive paste, in particular an electrically conductive adhesive.

11. The housing according to claim 1, wherein the electrically conductive material comprises an electrically conductive sheet-like structure, in particular an electrically conductive film or an electrically conductive strip.

12. The housing according to claim 1, wherein the first contact surface and the second contact surface are in direct contact with one another or touch one another.

13. The housing according to claim 1, wherein the second contact surface comprises a contact pad, preferably a tin-plated contact pad, particularly preferably a silver-free and/or gold-free contact pad.

14. The housing according to claim 1, wherein the first and second contact surface comprise functional elements which correspond to one another for the form-fitting joining of the components, wherein the surfaces of the functional elements are produced from an electrically conductive material or comprise such an electrically conductive material.

15. A brake device, for a motor vehicle, comprising at least one control unit with a housing according claim 1.

16. The housing according to claim 1, wherein the at least one electronic component is a circuit board.
